(19) United States
(12) Patent Application Publication
(10) Pub. No.: US 2005/0106826 A1
(43) Pub. Date: May 19, 2005

(54) Method for manufacturing semiconductor device

(76) Inventor: Hideki Oguma, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/958,587

(22) Filed: Oct. 6, 2004

(30) Foreign Application Priority Data
Oct. 7, 2003 (JP) 2003-348567

(51) Int. Cl. H01L 21/336; H01L 21/8234; H01L 21/3205; H01L 21/4763; H01L 21/302

(52) U.S. Cl. 438/301; 438/197; 438/585; 438/719; 438/712

(57) ABSTRACT

A method of manufacturing a semiconductor device is disclosed, which comprises forming a silicon layer above a semiconductor substrate, forming a photoresist mask above the silicon layer, and dry-etching the silicon layer using the photoresist mask as an etching mask in a manner that a byproduct layer containing silicon and silicon oxide is deposited on exposed surfaces of the photoresist mask during dry-etching the silicon layer, in which a ratio of an amount of the silicon to an amount of the silicon oxide is 1 or more.

### CROSS-REFERENCE TO RELATED APPLICATIONS

This application is based upon and claims the benefit of priority from prior Japanese Patent Application No. 2003-348567, filed Oct. 7, 2003, the entire contents of which are incorporated herein by reference.

### BACKGROUND OF THE INVENTION

1. Field of the Invention

The present invention relates to a method of manufacturing a semiconductor device, including a step of dry-etching a silicon layer.

2. Description of the Related Art

Dry etching of a polysilicon layer is used as an etching process. Such a dry-etching process comprises, for example, forming a resist mask on a polysilicon layer formed on a semiconductor substrate via an insulating film and etching the polysilicon layer using the resist mask as an etching mask by a two-stage RIE (Reactive Ion Etching) process. During the first stage RIE process, the polysilicon layer is etched at high speed. This etching for the polysilicon layer is normally carried out under conditions that the etching does not have selectivity with regard to the polysilicon layer on the one hand and the insulating film and the semiconductor substrate on the other hand. This process is stopped when the etching has progressed to the vicinity of the bottom of the polysilicon layer to avoid etching the insulating film and the semiconductor substrate. Subsequently, the second stage RIE process is executed for the polysilicon layer under conditions that the second stage RIE process has selectivity with regard to the polysilicon layer and the insulating film, so that the remaining part of the polysilicon layer, i.e., the bottom portion thereof, is removed.

The strength of the resist mask decreases in accordance with the size of a resist pattern (2001 DRY PROCESS INTERNATIONAL SYMPOSIUM P. 17 Study of sub-30 nm gate Etching Technology M. Nagase, et. al.). It is known that when the resist mask has a pattern width of 110 nm or less, the resist pattern is deformed during an RIE process executed on an underlying layer (i.e., the polysilicon layer in the above example) to be etched. When the polysilicon layer is etched with the resist pattern deformed, a layer with a predetermined pattern (that is, a predetermined shape and predetermined dimensions) is not obtained.

This problem also arises in the etching by the two-stage stage RIE (Reactive Ion Etching) process, and when the resist mask has a pattern width of 110 nm or less, the resist pattern is deformed. Thus, a polysilicon layer with a predetermined pattern is not obtained.

### BRIEF SUMMARY OF THE INVENTION

According to an aspect of the present invention, there is provided a method of manufacturing a semiconductor device comprising:
forming a silicon layer above a semiconductor substrate;
forming a photoresist mask above the silicon layer, and
dry-etching the silicon layer using the photoresist mask as an etching mask in a manner that a byproduct layer containing silicon and silicon oxide is deposited on exposed surfaces of the photoresist mask during dry-etching the silicon layer, in which a ratio of an amount of the silicon to an amount of the silicon oxide is 1 or more.

According to another aspect of the present invention, there is provided a method of manufacturing a semiconductor device comprising:
forming a gate oxide film on a semiconductor substrate,
forming a silicon layer to be processed to a gate electrode on the gate oxide film;
forming a photoresist mask above the silicon layer;
dry-etching the silicon layer using the photoresist mask as an etching mask to form the gate electrode in a manner that a byproduct layer containing silicon and silicon oxide is deposited on exposed surfaces of the photoresist mask during dry-etching the silicon layer, in which a ratio of an amount of the silicon to an amount of the silicon oxide is 1 or more, and.
implanting impurities into predetermined surface regions of the semiconductor substrate using the gate electrode as a mask to form source/drain regions in the predetermined surface regions.

### BRIEF DESCRIPTION OF THE SEVERAL VIEWS OF THE DRAWING

FIG. 1 is a sectional view of a structure in a process of manufacturing a MOS transistor according to an embodiment of the present invention;

FIG. 2 is a sectional view of the structure in a process of manufacturing the MOS transistor according to the embodiment, which follows the manufacturing process in FIG. 1;

FIG. 3 is a sectional view of the structure in a process of manufacturing the MOS transistor according to the embodiment, which follows the manufacturing process in FIG. 2;

FIG. 4 is a sectional view of the structure in a process of manufacturing the MOS transistor according to the embodiment, which follows the manufacturing process in FIG. 3;

FIG. 5 is a sectional view of the structure in a process of manufacturing the MOS transistor according to the embodiment, which follows the manufacturing process in FIG. 4;

FIG. 6 is a SEM (Scanning Electron Microscopy) photograph of a cross section of a polysilicon gate electrode resulting from an RIE process according to the embodiment of the present invention;

FIG. 7 is a SEM photograph of a cross section of a polysilicon gate electrode resulting from an RIE process according to the prior art;

FIG. 8 is a SEM photograph of a gate structure resulting from the RIE process according to the embodiment of the present invention, carried out on the polysilicon gate layer, as viewed from an upper surface of the gate structure;

FIG. 9 is a SEM photograph of a gate structure resulting from the RIE process according to the prior art, carried out on the polysilicon gate layer, as viewed from an upper surface of the gate structure;

FIG. 10 is a view showing an Auger electron spectrum of a surface layer (byproduct layer) of a photoresist mask resulting from the RIE process according to the embodiment of the present invention, carried out on the polysilicon layer; and

FIG. 11 is a view showing an Auger electron spectrum of a surface layer (byproduct layer) of a photoresist mask resulting from the RIE process according to the prior art, carried out on the polysilicon layer.

### DETAILED DESCRIPTION OF THE INVENTION

The present inventor considers that a resist pattern is deformed during a conventional process of dry-etching a polysilicon layer partly because ions of an etching gas collide against a resist mask during the dry-etching. The present inventor also considers that another cause is that a byproduct is deposited non-uniformly on the resist mask during the dry-etching to generate stress on the side surface of the resist mask.

An embodiment of the present invention will be described below with reference to the drawings.

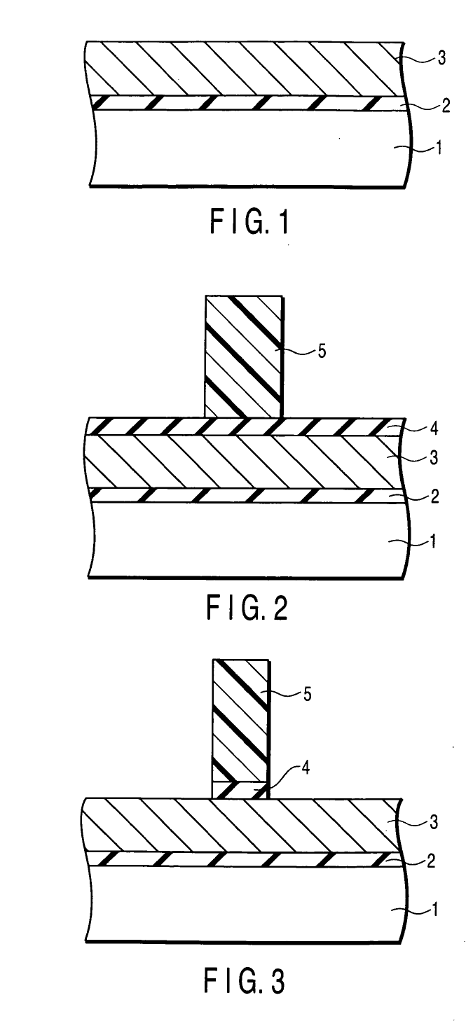

FIGS. 1 to 5 are sectional views of a structure in the respective manufacturing processes of a method of manufacturing a MOS transistor according to an embodiment of the present invention.

First, as shown in FIG. 1, a gate oxide film 2 made of silicon oxide is formed on a silicon substrate 1. Subsequently, a polysilicon film 3 of thickness 175 nm is deposited on the gate oxide film 2.

Then, as shown in FIG. 2, an antireflection film 4 of thickness 80 nm is formed on the polysilicon film 3. Subsequently, a photoresist mask 5 is formed on the antireflection film 4 by a photoresist coating and photolithography. The photoresist mask 5 has a pattern width of 110 nm or less and is used as a mask for forming a gate electrode according to this embodiment.

Then, as shown in FIG. 3, the antireflection film 4 is etched, using the photoresist mask 5 as an etching mask. Following this, the pattern width of the photoresist mask 5 and antireflection film 4 are reduced to 70 nm by slimming technique.

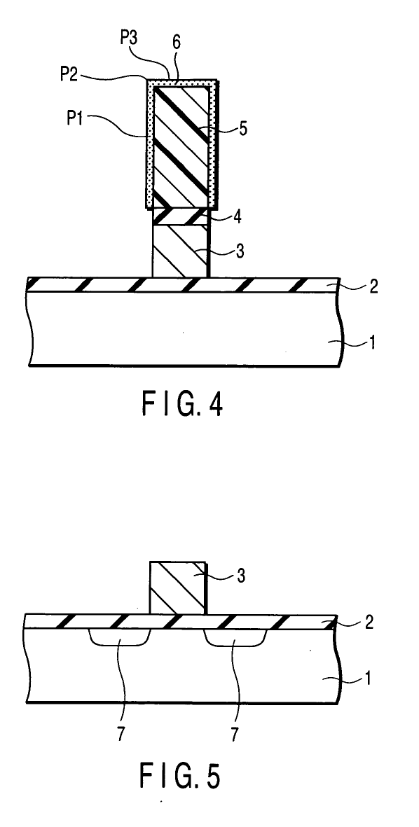

Then, the polysilicon layer 3 is etched by an RIE process for 60 seconds or more, using the photoresist mask 5 as an etching mask. The RIE process is executed using, for example, an ICP (Inductive Coupling Plasma) type plasma etching apparatus. A mixed gas containing an HBr gas, a Cl₂ gas, and an O₂ gas is used as an etching gas. The etching gas has selectivity with regard to the polysilicon layer 3 and the gate oxide film 2 made of silicon oxide. The etching is continued for at least 60 seconds in order to completely pattern the polysilicon layer 3. The O₂ has a gas flow of 4 sccm. The pressure in an etching apparatus (i.e., the pressure in an etching chamber) is 12 mTorr. Via this RIE process, a polysilicon gate electrode 3 as shown in FIG. 4 is provided. In FIG. 4, reference numeral 6 denotes a byproduct layer generated during etching of the polysilicon layer 3 by the RIE process.

According to the RIE process under these conditions, as shown in FIG. 4, the byproduct is deposited on an upper surface and a side surface of the photoresist mask 5. During the etching of the polysilicon layer 3, the photoresist mask 5 is not deformed, and the polysilicon gate electrode 3 with a predetermined shape and predetermined dimenSiOns is obtained. It has been confirmed that this effect is obtained, provided that the O₂ has a flow of 4 sccm or more and that the pressure in the etching chamber is 10 mTorr or more.

Subsequently, the photoresist mask 5 and the antireflection film 4 are removed by a known process. Then, impurities are implanted into predetermined regions of the surface of the silicon substrate 1 to form source/drain regions 7, using the polysilicon gate electrode 3 as a mask.

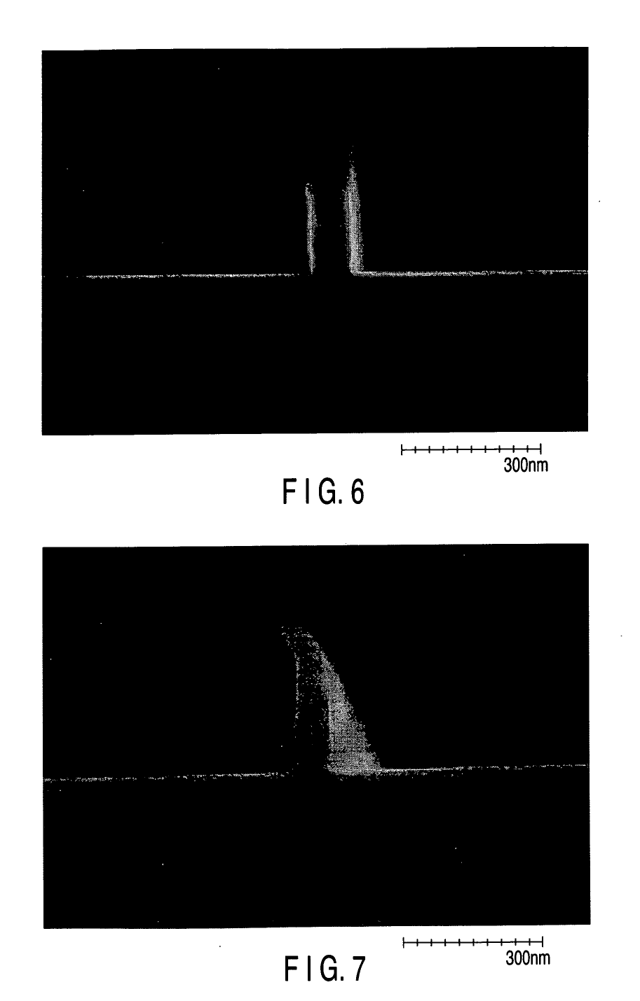

FIG. 6 is a SEM (Scanning Electron Microscopy) photograph of a cross section of the polysilicon gate electrode resulting from the RIE process according to the embodiment, executed on the polysilicon layer 3, and FIG. 7 is a SEM photograph of a cross section of a polysilicon gate electrode resulting from the conventional two-stage RIE process, executed on the polysilicon layer.

As shown in the SEM photograph in FIG. 6, the polysilicon gate electrode resulting from the RIE process according to the present embodiment has a predetermined pattern (i.e., a predetermined shape and a predetermined dimension). On the other hand, as shown in the SEM photograph in FIG. 7, the polysilicon gate electrode resulting from the conventional two-stage RIE process has a deformed pattern.

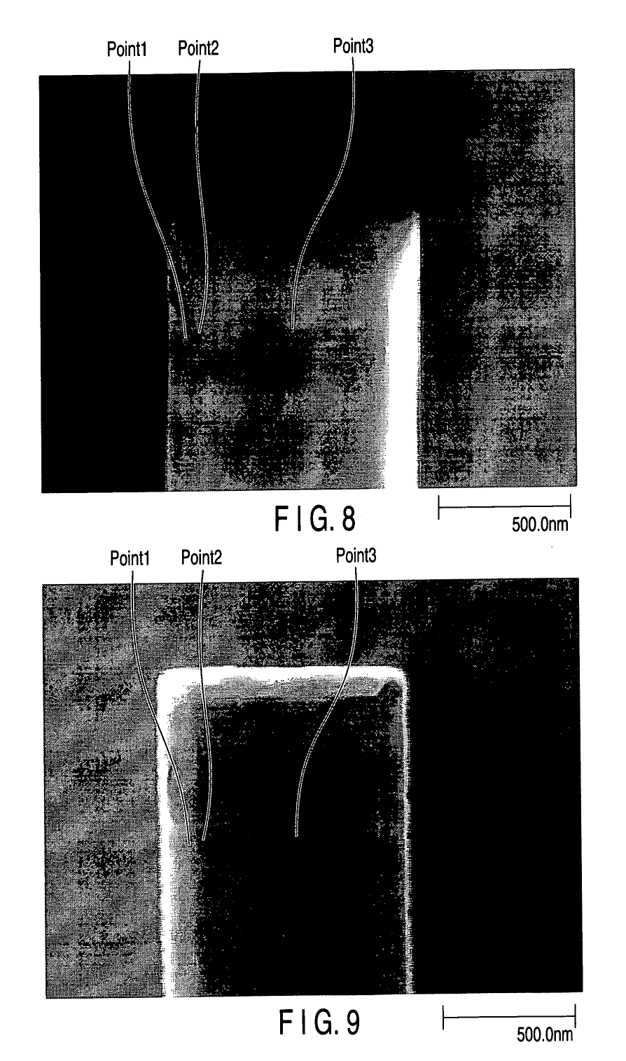

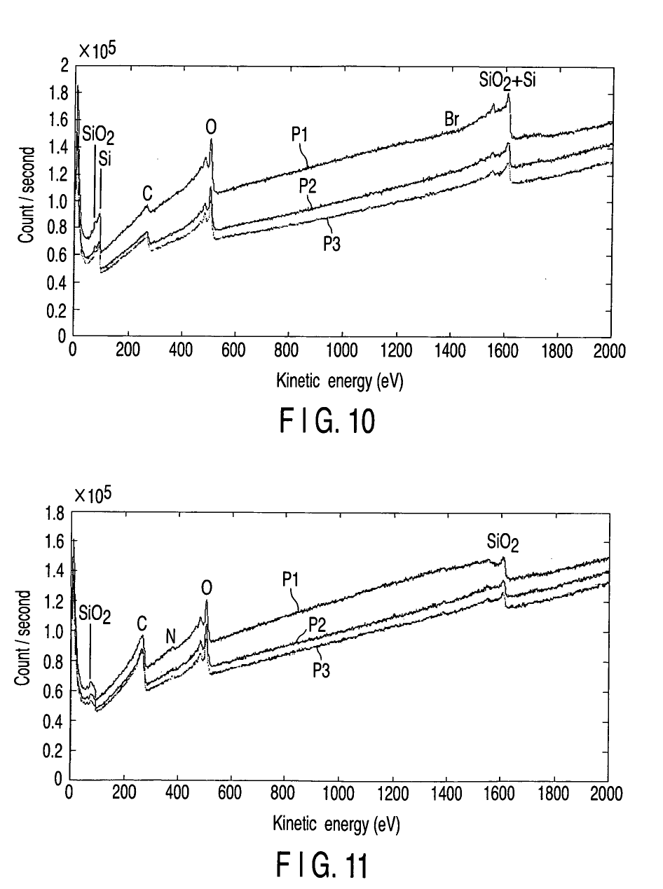

FIG. 8 is a SEM photograph of a gate structure resulting from the RIE process according to the embodiment, executed on the polysilicon layer 3, as viewed from an upper surface of the gate structure, and FIG. 9 is a SEM photograph of a gate structure resulting from the conventional two-stage RIE process, executed on the polysilicon layer 3, as viewed from an upper surface of the gate structure.

As shown in the SEM photograph in FIG. 8, according to the RIE process according to the present embodiment, executed on the polysilicon layer 3, the byproduct is deposited not only on the side surface but also the upper surface of the photoresist mask 5. In other words, the byproduct is deposited on all the exposed surfaces of the photoresist mask 5. The reason why the byproduct is thus deposited is thought to be that a sufficient amount of byproduct is generated because the polysilicon layer 3 is etched by the RIE for a long time, that is, at least 60 seconds and that when the pressure in the etching chamber is 12 mTorr, the byproduct is mainly deposited on the exposed surfaces of the photoresist mask 5 without being expelled from the etching chamber.

On the other hand, as shown in the SEM photograph in FIG. 9, according to the conventional two-stage RIE process executed on the polysilicon layer 3, the byproduct is deposited on the side surface but almost not on the upper surface of the photoresist mask 5. The reason why such a deposition form results is thought to be that under the conditions for the first stage RIE executed on the polysilicon layer 3, the pressure in the etching chamber is low so that most of the byproduct is expelled from the chamber, and that under the conditions for the second stage RIE executed also on the polysilicon layer 3, the pressure in the etching chamber is high so that most of the byproduct will remain in the etching chamber, however, the etching time is normally about 20 seconds, which is not long enough to generate a sufficient amount of byproduct to be deposited on all the exposed surfaces of the photoresist mask 5.

FIG. 10 shows an Auger electron spectrum of a surface layer (byproduct layer 6) of the polysilicon gate electrode resulting from the RIE process according to the embodiment, executed on the polysilicon layer 3, and FIG. 11 shows an Auger electron spectrum of a surface layer (byproduct layer 6) of the polysilicon gate electrode resulting from the conventional two-stage RIE process, executed on the polysilicon layer 3.

In FIGS. 10 and 11, characteristic curves denoted by P1 to P3 correspond to parts of the photoresist mask 5 denoted by P1 to P3 in FIG. 4. In FIG. 4, P1 designates a side surface of the photoresist mask 5. P2 designates the corner portion between an upper surface and the side surface of the photoresist mask 5. P3 designates the upper surface of the photoresist mask 5. Accordingly, the curve denoted by P1 in FIGS. 10 and 11 shows an Auger electron spectrum of the side surface of the photoresist mask 5 in FIG. 4. The curve denoted by P2 in FIGS. 10 and 11 shows an Auger electron spectrum of the corner portion between the upper surface and side surface of the photoresist mask 5 in FIG. 4. The curve denoted by P3 in FIGS. 10 and 11 shows an Auger electron spectrum of the upper surface of the photoresist mask 5 in FIG. 4.

FIGS. 10 and 11 indicate that the amount (count/sec) of silicon (Si) in the surface layer of the photoresist mask 5 according to the present embodiment is larger than that in the surface layer of the photoresist mask 5 according to the prior art. For example, for the side surface P1 of the photoresist mask 5 (FIG. 4), the amount of silicon (Si) in the surface layer according to the present embodiment is approximately 0.9×10⁵ c/s, and it is considerably large as compared with the amount of silicon in the surface layer according to the prior art. In other words, according to the present embodiment, the byproduct layer 6 containing a larger amount of silicon than that according to the prior art is formed on the side surface P1 of the photoresist mask 5. Also in the side surface P1 of the photoresist mask 5 (FIG. 4), the amount of silicon oxide (SiO₂) in the surface layer according to the present embodiment is approximately 0.85×10⁵ c/s, and Si/SiO₂≧1, as seen from FIGS. 10 and 11. On the other hand, as for the surface layer at the side surface P1 according to the prior art, Si/SiO₂<1, also as seen from FIGS. 10 and 11. These results indicate that in the present embodiment, the byproduct layer 6 containing an amount of silicon that meets Si/SiO₂≧1 is deposited on the side surface P1 of the photoresist mask 6.

FIGS. 10 and 11 also indicate that, for example, for the upper surface P3 of the photoresist mask 5 (FIG. 4), the amount of silicon (Si) in the surface layer according to the present embodiment is approximately 0.67×10⁵ c/s, and it is considerably large as compared with the amount of silicon in the surface layer according to the prior art. In other words, according to the present embodiment, the byproduct layer 6 containing a larger amount of silicon than that according to the prior art is formed on the upper surface P3 of the photoresist mask 5. Also in the upper surface P3 of the photoresist mask 5, the amount of silicon oxide (SiO₂) in the surface layer according to the present embodiment is approximately 0.63×10⁵ c/s, and Si/SiO₂≧1, as seen from FIGS. 10 and 11. On the other hand, as for the surface layer at the upper surface P3 according to the prior art, Si/SiO₂<1, also as seen from FIGS. 10 and 11. These results indicate that in the present embodiment, the byproduct layer 6 containing an amount of silicon that meets Si/SiO₂≧1 is deposited on the upper surface P3 of the photoresist mask 6.

As described above, with the RIE process of the present embodiment executed on the polysilicon layer 3, the byproduct layer 6 is deposited not only on the side surface but also on the upper surface of the photoresist mask 5 (FIG. 8). Furthermore, the byproduct layer 6 contains a large amount of silicon. These are considered be the reason why the method of the present embodiment can prevent deformation of the photoresist mask 5, and consequently, prevent deformation of the polysilicon gate electrode 3.

The byproduct layer 6 containing a large amount of silicon functions as a hard film. The byproduct layer 6 functioning as a hard film is deposited on all the exposed surfaces, that is, the side surface and upper surface of the photoresist mask 5, during the RIE process of the polysilicon layer 3. Thus, all the exposed surfaces of the resist mask 5 is covered with the byproduct layer 6 functioning as a hard film, during the RIE process of the polysilicon layer 3. This suppresses possible damage to the resist mask 5 during the RIE process of the polysilicon layer 3 when ions of the etching gas collide against the resist mask 5. Furthermore, since the byproduct layer 6 is deposited on all the exposed surfaces (that is, the side surface and upper surface) of the photoresist mask 5, the photoresist mask 5 has no portions weak to the collision of the etching gas ions. Also, since the byproduct layer 6 is deposited on all the exposed surfaces (that is, the side surface and upper surface) of the photoresist mask 5, the photoresist mask 5 does not undergo any local stress. These are considered to be the reasons why the photoresist mask 5 is not deformed. Further, it is considered that since the photoresist mask 5 is thus not deformed during the RIE process of the polysilicon layer 3, the polysilicon gate electrode 3, obtained by subjecting the polysilicon layer 3 to the RIE process, using the photoresist mask 5 as an etching mask, has a predetermined pattern (i.e., a predetermined shape and a predetermined dimension) as shown in the SEM photograph in FIG. 6.

As described above, according to the present embodiment, the byproduct layer 6 containing a large amount of silicon is deposited on all the exposed surfaces (that is, the side surface and upper surface) of the photoresist mask 5 during the RIE process of the polysilicon layer 3. This prevents the photoresist mask 5 from being deformed, thus providing a polysilicon gate electrode 3 with a predetermined shape and predetermined dimension.

The present invention is not limited to the above embodiment. For example, the above embodiment has been described in conjunction with the etching for forming the pattern of the gate electrode of the polysilicon layer. However, the present invention is similarly applicable to the etching of a gate electrode including a polysilicon layer, for example, a polycide gate electrode, instead of the gate electrode of the polysilicon layer. Moreover, besides the etching for forming the pattern of the gate electrode, the present invention is similarly applicable to etching for forming other layer patterns. Furthermore, the present invention is not limited to the etching of the polysilicon layer but is applicable to the etching of a single-crystal silicon layer and an amorphous silicon layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device comprising:
forming a silicon layer above a semiconductor substrate;
forming a photoresist mask above the silicon layer, and
dry-etching the silicon layer using the photoresist mask as an etching mask in a manner that a byproduct layer containing silicon and silicon oxide is deposited on exposed surfaces of the photoresist mask during dry-etching the silicon layer, in which a ratio of an amount of the silicon to an amount of the silicon oxide is 1 or more.

2. The method of manufacturing a semiconductor device according to claim 1, wherein the byproduct layer is deposited on an upper surface and a side surface of the photoresist mask.

3. The method of manufacturing a semiconductor device according to claim 1, wherein the photoresist mask has a width of 110 nm or less.

4. The method of manufacturing a semiconductor device according to claim 1, wherein when the photoresist mask is used as the etching mask to dry-etch the silicon layer, a mixed gas containing an HBr gas, a Cl₂ gas, and an O₂ gas is used as an etching gas.

5. The method of manufacturing a semiconductor device according to claim 4, wherein the flow rate of the O₂ gas is set to be 4 sccm or more.

6. The method of manufacturing a semiconductor device according to claim 4, wherein a pressure in an etching chamber when the silicon layer is dry-etched is set to be 10 mTorr or more.

7. The method of manufacturing a semiconductor device according to claim 4, wherein the dry-etching is carried out for 60 seconds or more.

8. The method of manufacturing a semiconductor device according to claim 1, wherein the silicon layer is a polysilicon layer.

9. The method of manufacturing a semiconductor device according to claim 1, wherein after the silicon layer has been formed above the semiconductor substrate, an antireflection film is formed on the silicon layer, and the photoresist mask is formed on the antireflection film.

10. The method of manufacturing a semiconductor device according to claim 9, wherein after a width of the antireflection film and the photoresist mask has been reduced, the dry-etching of the silicon layer is carried out, using the photoresist mask whose width has been reduced as the etching mask.

11. A method of manufacturing a semiconductor device comprising:
forming a gate oxide film on a semiconductor substrate,
forming a silicon layer to be processed to a gate electrode on the gate oxide film;,
forming a photoresist mask above the silicon layer;
dry-etching the silicon layer using the photoresist mask as an etching mask to form the gate electrode in a manner that a byproduct layer containing silicon and silicon oxide is deposited on exposed surfaces of the photoresist mask during dry-etching the silicon layer, in which a ratio of an amount of the silicon to an amount of the silicon oxide is 1 or more, and
implanting impurities into predetermined surface regions of the semiconductor substrate using the gate electrode as a mask to form source/drain regions in the predetermined surface regions.

12. The method of manufacturing a semiconductor device according to claim 11, wherein the byproduct layer is deposited on an upper surface and a side surface of the photoresist mask.

13. The method of manufacturing a semiconductor device according to claim 11, wherein the photoresist mask has a width of 110 nm or more.

14. The method of manufacturing a semiconductor device according to claim 11, wherein when the photoresist mask is used as the etching mask to dry-etch the silicon layer, a mixed gas containing an HBr gas, a Cl₂ gas, and an O₂ gas is used as an etching gas.

15. The method of manufacturing a semiconductor device according to claim 14, wherein the flow rate of the O₂ gas is set to be 4 sccm or more.

16. The method of manufacturing a semiconductor device according to claim 14, wherein a pressure in an etching chamber when the silicon layer is dry-etched is set to be 10 mTorr or more.

17. The method of manufacturing a semiconductor device according to claim 14, wherein the dry-etching is carried out for 60 seconds or more.

18. The method of manufacturing a semiconductor device according to claim 11, wherein the gate oxide film is a silicon oxide film.

19. The method of manufacturing a semiconductor device according to claim 11, wherein after the silicon layer has been formed on the gate oxide film, an antireflection film is formed on the silicon layer, and the photoresist mask is formed on the antireflection film.

20. The method of manufacturing a semiconductor device according to claim 19, wherein after a width of the antireflection film and the photoresist mask has been reduced, the dry-etching of the silicon layer is carried out, using the photoresist mask whose width has been reduced as the etching mask.
